(19) United States
(12) Patent Application Publication
(10) Pub. No.: US 2023/0176473 A1
(43) Pub. Date: Jun. 8, 2023

(54) POD FOR CONTAINING A PHOTOMASK

(71) Applicant: CHI-CHUNG CHEN, Tainan City (TW)

(72) Inventor: CHI-CHUNG CHEN, Tainan City (TW)

(21) Appl. No.: 17/858,081

(22) Filed: Jul. 6, 2022

(30) Foreign Application Priority Data
Dec. 8, 2021 (TW) 110145910

(51) Int. Cl. G03F 1/66; G02B 7/02

(52) U.S. Cl. CPC G03F 1/66; G02B 7/02

(57) ABSTRACT

A pod is used to contain a photomask formed with two parallel faces. The pod includes two lens units respectively connected to two portions of the pod corresponding to the faces of the photomask. Each of the lens units includes a lens of a transmittance equal to or larger than 90%. The lens of each of the lens units includes a visible portion equal to or larger than a pattern formed on the photomask. Light is allowed to reach or leave the photomask via the visible portion of the lens of each of the lens units when the photomask is contained in the pod.

### BACKGROUND OF INVENTION

### 1. Field of Invention

The present invention relates to a photomask and, more particularly, to a pod for containing a photomask.

### 2. Related Prior Art

Photomasks are used in photolithography. During storage or transportation of a photomask, the photomask is very likely to suffer defects such as particles or smog caused by materials such as gas used in the photolithography, particles peeled from parts used in the photolithography, oil dropped from any of the parts, and/or other contaminants caused by deposition of and chemical reaction of gaseous molecules. Therefore, during the transportation or storage, the photomask is contained in a highly clean, air-tight and antistatic pod, Reticle SMIF Pod (“RSP”) to avid contamination.

However, in the photolithography or inspection of a face of the photomask, the photomask has to be taken from the pod. The face of the photomask can be contaminated by particles or any other contaminants. Abrasion or collision can happen to the photomask to produce particles or static charges that render the face of the photomask more vulnerable to contamination.

The present invention is therefore intended to obviate or at least alleviate the problems encountered in the prior art.

### SUMMARY OF INVENTION

It is an objective of the present invention to provide a pod for protectively containing a photomask in lithography.

It is another objective of the present invention to provide a pod for protectively containing a photomask in inspection of the photomask.

To achieve the foregoing objectives, the pod includes a base, a cover, a lower lens unit, and an upper lens unit. The base includes a supporting frame. The cover includes a supporting frame corresponding to the supporting frame of the base and a continuous wall extending around the supporting frame of the cover and extending toward the base. A chamber is defined between the cover and the base to contain the photomask when the cover is connected to the base. The lower lens unit is connected to the supporting frame of the base and formed with a lens of a transmittance equal to or larger than 90%. The lens of the lower lens unit includes a visible portion equal to or larger than a pattern formed on the photomask. The upper lens unit is connected to the supporting frame of the cover and formed with a lens of a transmittance equal to or larger than 90%. The lens of the upper lens unit includes a visible portion equal to or larger than the pattern of the photomask. Light is allowed to reach or leave the photomask via the visible portion of the lens of each of the lower and upper lens units when the photomask is contained in the pod.

Other objectives, advantages and features of the present invention will be apparent from the following description referring to the attached drawings.

### BRIEF DESCRIPTION OF DRAWINGS

The present invention will be described via detailed illustration of two embodiments referring to the drawings wherein:

FIG. 1 is a perspective view of a pod according to the first embodiment of the present invention;

FIG. 2 is an exploded view of the pod shown in FIG. 1;

FIG. 3 is another exploded view of the pod shown in FIG. 1;

FIG. 4 is a top view of the pod shown in FIG. 1;

FIG. 5 is a side view of the pod shown in FIG. 1;

FIG. 6 is a cross-sectional view of the pod shown in FIG. 1 during lithography;

FIG. 7 is a cross-sectional view of the pod shown in FIG. 1 during inspection of a photomask;

FIG. 8 is an exploded view of a pod according to the second embodiment of the present invention; and

FIG. 9 is a perspective view of the pod shown in FIG. 8.

### DETAILED DESCRIPTION OF EMBODIMENTS

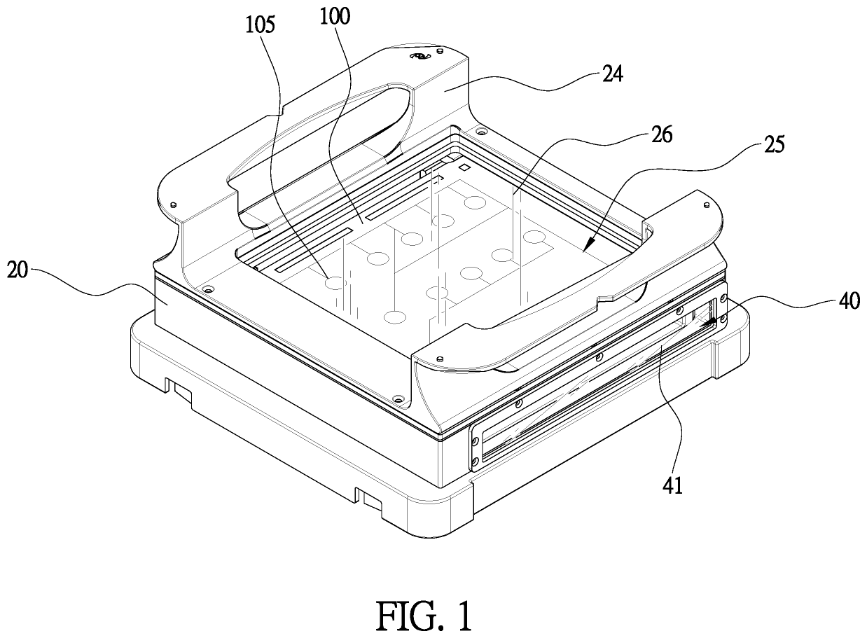

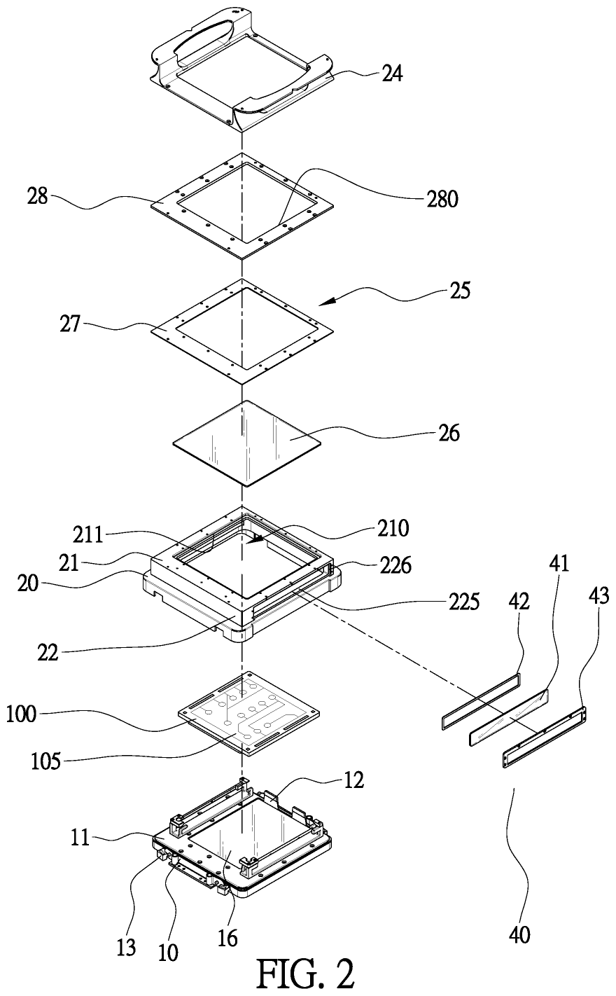

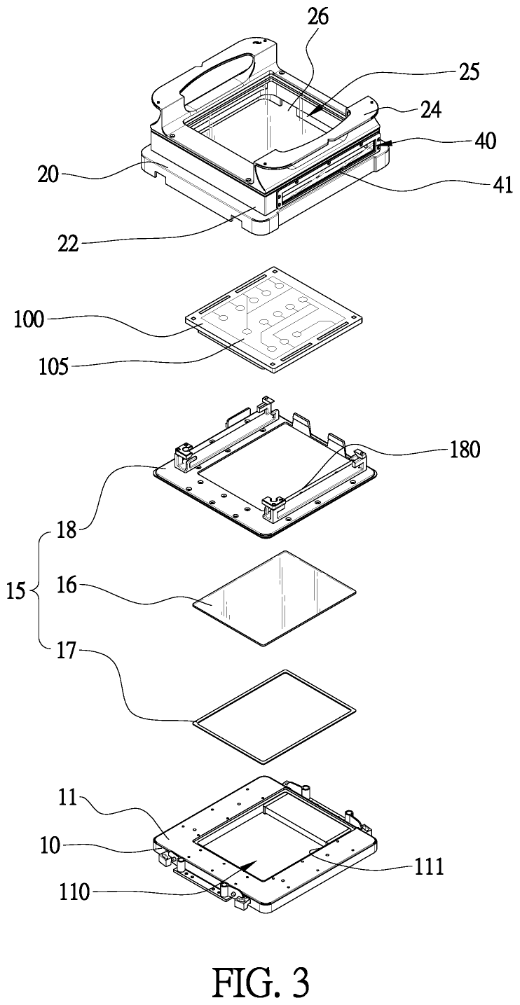

Referring to FIGS. 1 through 5, a photomask 100 formed with a pattern 105 can be contained in and hence protected by a pod according to a first embodiment of the present invention. The pod includes a base 10 and a cover 20. The base 10 can be covered by the cover 20. The base 10 includes a supporting frame (or “baseplate”) 11. The cover 20 includes a continuous wall 22 extending around a supporting frame 21. The supporting frame 21 is shaped corresponding to the supporting frame 11. The continuous wall 22 extends toward the base 10. A chamber is defined between the cover 20 and the base 10 when the continuous wall 22 of the cover 20 is connected to the supporting frame 11 of the base 10. The chamber is used to contain the photomask 100. The base 10 and the cover 20 are made of metal, plastic, or any other proper material.

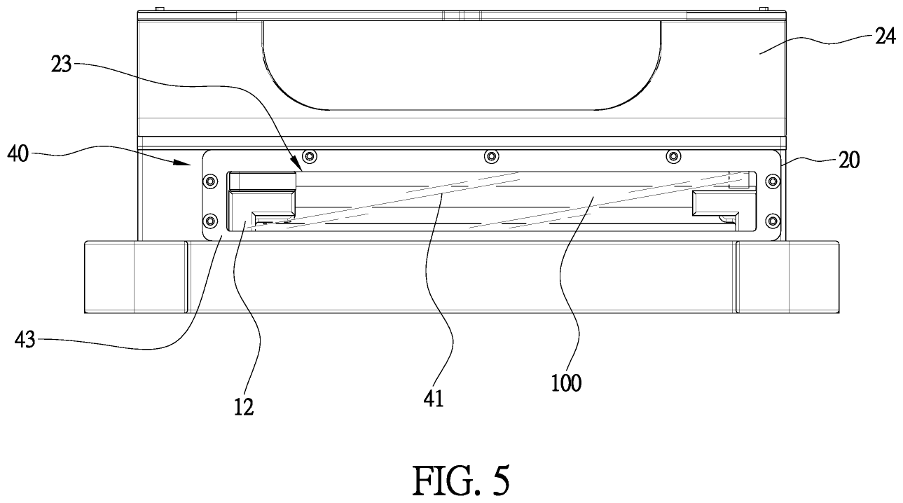

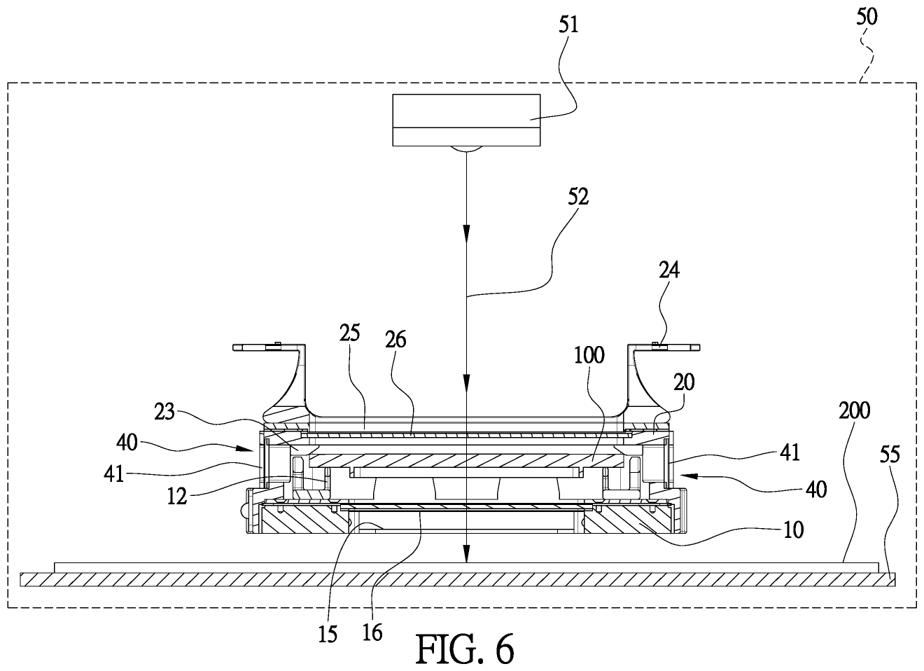

A confining mechanism 12 is provided on the supporting frame 11 of the base 10 corresponding to the cover 20. A clipping mechanism 23 (FIGS. 5 and 6) is provided beneath the supporting frame 21 of the cover 20 corresponding to the base 10. The confining mechanism 12 is used with the clipping mechanism 23 to keep the photomask 100 in position in the chamber. In addition, a locking mechanism 13 can be used between the base 10 and the cover 20 to lock the cover 20 to the base 10.

Preferably, a to-be-clamped mechanism 24 is used. The to-be-clamped mechanism 24 includes two fins (not numbered) extending from a frame (not numbered). The frame of the to-be-clamped mechanism 24 is connected to the supporting frame 21 of the cover 20. The fins of the to-be-clamped mechanism 24 can be clamped by a robot that is used to hold and transport the pod. Thus, the robot is operable to move the cover 20 via the to-be-clamped mechanism 24.

A lower lens unit 15 is connected to the supporting frame 11. The lower lens unit 15 is used to render a lower face of the photomask 100 accessible for light when the photomask 100 is located on the lower lens unit 15. To this end, the lower lens unit 15 includes a transparent portion equal to or larger than the pattern 105 of the photomask 100.

An upper lens unit 25 is connected to the supporting frame 21. The upper lens unit 25 is used to render an upper face of the photomask 100 accessible for light when the photomask 100 is located below the upper lens unit 25. To this end, the upper lens unit 25 includes a transparent portion equal to or larger than the pattern 105 of the photomask 100. The upper lens unit 25 is configured corresponding to the lower lens unit 15.

Moreover, the cover 20 includes two lateral lens units 40 provided on two opposite portions of the continuous wall 22. Each of the lateral lens units 40 is used to render the photomask 100 accessible for light when the photomask 100 is located in the pod. To this end, each of the lateral lens units 40 includes a transparent portion equal to or larger than the lateral face of the photomask 100.

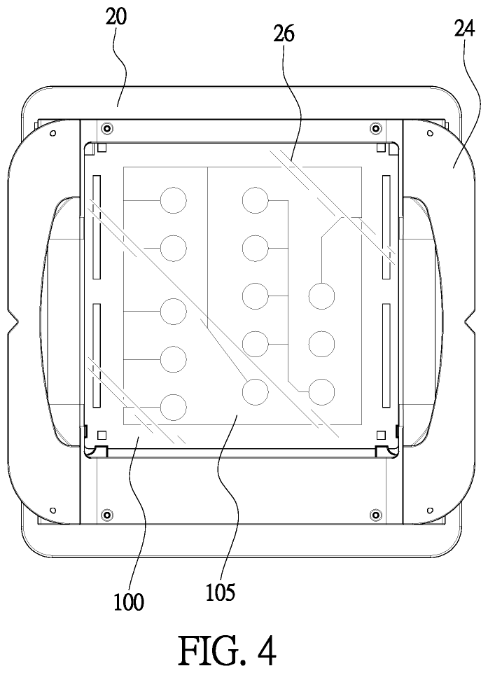

The lower lens unit 15 includes a lens 16. The upper lens unit 25 includes a lens 26. Each of the lateral lens units 40 includes a lens 41. The lenses 16, 25 and 41 are made of at least 99.995% pure quartz doped with less than 5 ppm of metal so that the transmittance is equal to or larger than 90% regarding ultraviolet light, visible light and infrared light. Thus, light emitted from a light source is allowed to efficiently enter the pod and reach the photomask 100 through the lens 16 or 26 (FIG. 4) or one of the lenses 41 (FIG. 5). Then, the light is allowed to leave the pod through the lens 26 or 16 or the remaining one of the lenses 41.

Preferably, the lower lens unit 15 includes a sealing ring 17 and a pressing frame 18 in addition to the lens 16. The sealing ring 17 extends along a continuous edge of the lens 16. The pressing frame 18 includes a window 180 shaped like the lens 16. The profile of the window 180 is marginally smaller than the lens 16.

Accordingly, the supporting frame 11 includes a window 110 in communication with a countersink bore 111. The window 110 is shaped like the countersink bore 111. The profile of the window 110 is marginally smaller than the profile of the countersink bore 111.

The sealing ring 17 and the lens 16 are inserted in the countersink bore 111. Then, the pressing frame 18 is connected to the supporting frame 11, thereby keeping the sealing ring 17 and the lens 16 between the supporting frame 11 and the pressing frame 18.

Preferably, the upper lens unit 25 includes a sealing ring 27 and a pressing frame 28 in addition to the lens 26. The sealing ring 27 includes an internal continuous margin extending along a continuous edge of the lens 26. The pressing frame 28 is shaped like the sealing ring 27. The pressing frame 28 includes a window 280 shaped like the lens 26. The profile of the window 280 is marginally smaller than the lens 26.

Accordingly, the supporting frame 21 includes a window 210 in communication with a countersink bore 211. The window 210 is shaped like the countersink bore 211. The profile of the window 210 is marginally smaller than the profile of the countersink bore 211.

The sealing ring 27 and the lens 26 are inserted in the countersink bore 211. Then, the pressing frame 28 is connected to the supporting frame 21, thereby keeping the sealing ring 27 and the lens 26 between the supporting frame 21 and the pressing frame 28. The frame of the to-be-clamped mechanism 24 includes a window (not numbered) corresponding to the window 280 so that the to-be-clamped mechanism 24 does not cover the window 280.

Each of the lateral lens unit 40 includes a sealing ring 42 and a pressing frame 43 in addition to the lens 41. The sealing ring 42 extends along a continuous edge of the lens 41. The pressing frame 43 includes a window (not numbered) shaped like the lens 41. The profile of the window of the pressing element 43 is marginally smaller than the lens 41.

Accordingly, the continuous wall 22 of the cover 20 includes two opposite lateral windows 225 and two opposite countersink bores 226. Each of the windows 225 is in communication with a corresponding one of the countersink bores 226.

In assembly, the lens 41 and sealing ring 42 of each of the lateral lens units 40 are inserted in a corresponding one of the countersink bores 226. Then, the pressing frame 43 of each of the lateral lens units 40 is connected to a portion of the continuous wall 22 of the cover 20 so that the lens 41 and sealing ring 42 of each of the lateral lens units 40 are kept between the pressing frame 43 of the corresponding lens unit 40 and a corresponding portion of the continuous wall 22 of the cover 20.

Referring to FIG. 6, in photolithography, the pod is inserted in a photolithographic machine 50 including a light source 51 and a carrier 55. The carrier 55 is used to transport a wafer 200. The light source 51 is operable to cast a ray 52 onto the photomask 100 in the pod via the lens 26 of the upper lens unit 25. Most of the light in the ray 52 penetrates the photomask 100. However, some of the light in the ray 52 is blocked by the pattern 105 of the photomask 100. Then, the ray 52 leaves the pod via the lens 15 of the lower lens unit 15. Finally, the ray 52 is used to transfer the pattern 105 to the wafer 200.

In some cases, the pattern 105 is formed on a reflective face of the photomask 100. The ray 52 is expected to bounce from the reflective face of the photomask 100 instead of penetrate the photomask 100. In such cases, the ray 52 reaches the photomask 100 in the pod via the lens 16 or 26, bounces from the photomask 100, and leaves the pod through the same lens 16 or 26.

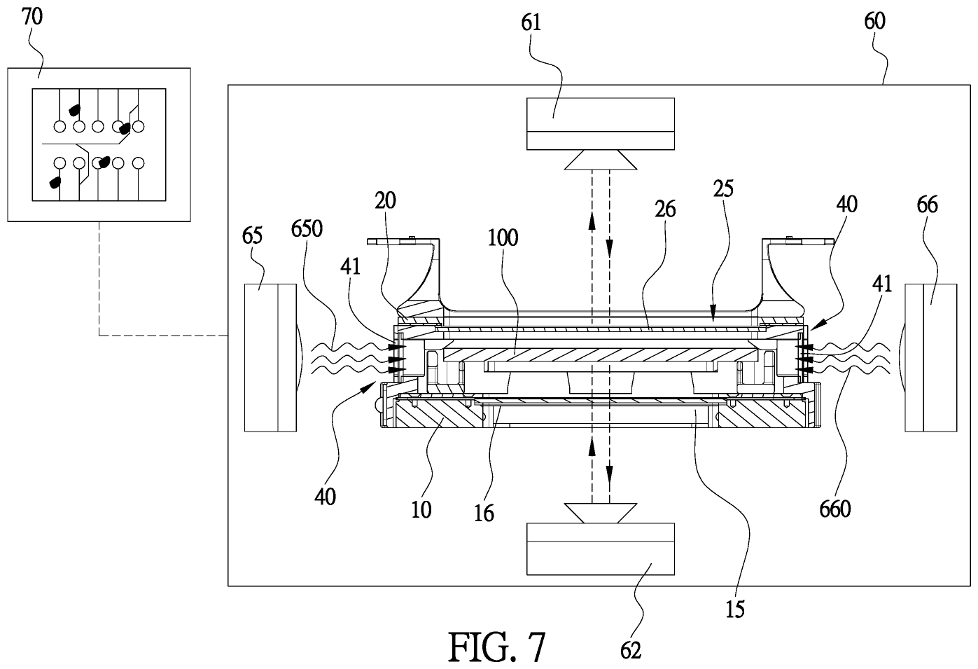

Referring to FIG. 7, in inspection of the wafer 200, the pod is inserted in an inspecting machine 60 including two image sensors 61 and 62 such as CCD or CMOS sensors. The image sensor 61 is located above the pod while the image sensor 62 is located below the pod. The inspecting machine 60 further includes two light sources 65 and 66 on two opposite sides of the pod. The light source 65 is operable to cast a ray 650 while the light source 66 is operable to cast a ray 660. The rays 650 and 660 enter the pod via lenses 41 of the lateral lens units 40 of the cover 20 and reach two faces of the photomask 100. The image sensors 61 and 62 detect contaminants, if any, on the faces of the photomask 100 while the pod protectively covers the photomask 100. Then, the image sensors 61 and 62 send results of the inspection to a display (not shown) electrically connected to the inspecting machine 60.

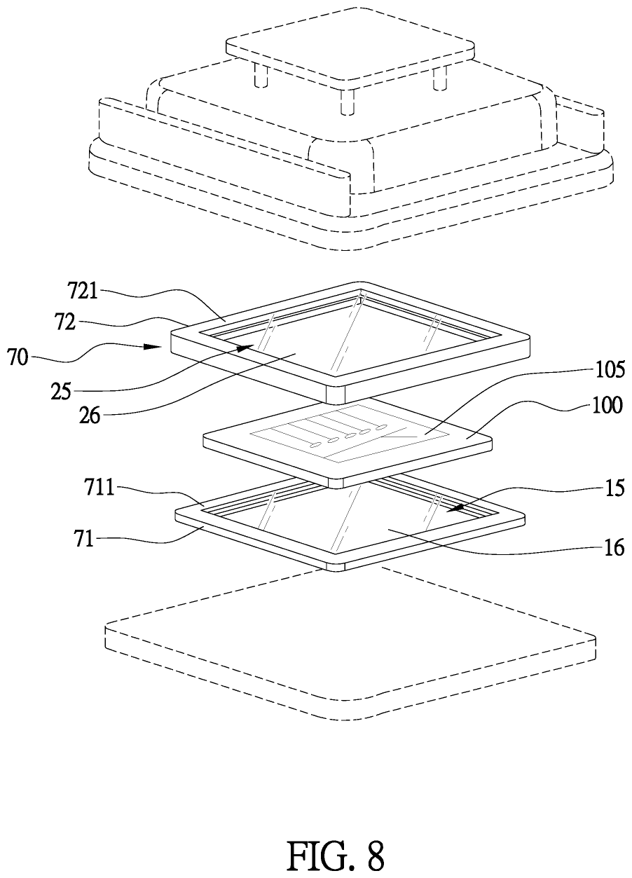

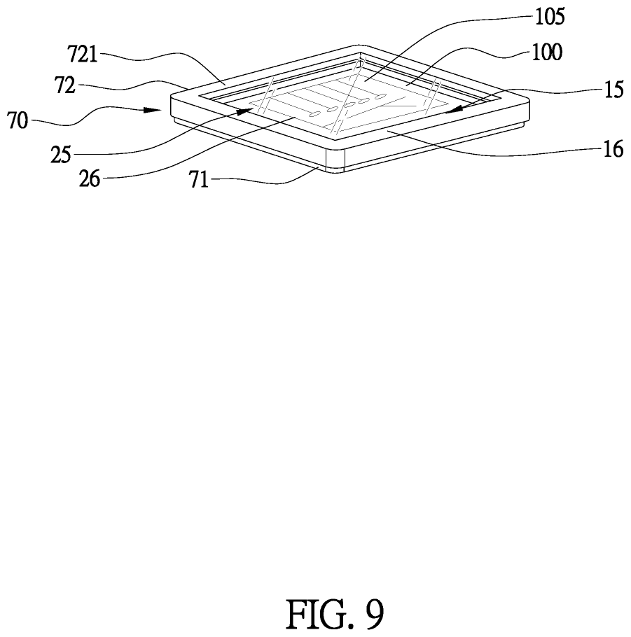

Referring to FIGS. 8 and 9, there is a pod 70 according to a second embodiment of the present invention. Preferably, the pod 70 is used as an internal pod 70 in the pod according to the first embodiment. However, the pod 70 can be used independent of the pod according to the first embodiment. The photomask auxiliary pod 70 includes a base 71 and a cover 72. Preferably, the base 71 and the cover 72 are made of metal. The base 71 includes a frame 711. The cover 72 includes a frame 721 corresponding to the frame 711. The cover 72 further includes a continuous wall extending around the frame 721 and extending toward the base 71. When the cover 20 is connected to the base 10, there is a chamber between them to contain the photomask 100.

The frame 711 of the base 71 is equipped with a lower lens unit 15. The frame 721 of the cover 72 includes an upper lens unit 25. The lower lens unit 15 includes a lens 16. The upper lens unit 25 includes a lens 26.

Although not shown, it is preferred that the pod 70 further includes two lateral lens units 40 on two opposite portions of the continuous wall of the cover 72. The profile of the lateral lens units 40 is larger than the profile of lateral faces of the photomask 100. Each of the lateral lens units 40 includes a lens 41.

Light can be cast onto the photomask 100, which is inserted in the pod 70, through each of the lenses 15, 25 and 41. Light is allowed to leave the pod 70 via each of the lenses 15, 25 and 41.

As discussed above, the pod of the present invention always protectively covers the photomask 100 during the photolithography or inspection of the photomask 100. The risks of contamination of the photomask 100 are minimized. Thus, the photolithography can be executed efficiently.

The present invention has been described via illustration of the embodiments. Those skilled in the art can derive variations from the embodiments without departing from the scope of the present invention. Therefore, the embodiments shall not limit the scope of the present invention defined in the claims.

1. A pod for containing a photomask formed with a pattern, the pod comprising:
a base comprising a supporting frame;
a cover comprising a supporting frame corresponding to the supporting frame of the base and a continuous wall extending around the supporting frame of the cover and extending toward the base, wherein a chamber is defined between the cover and the base to contain the photomask when the cover is connected to the base;
a lower lens unit connected to the supporting frame of the base and formed with a lens of a transmittance equal to or larger than 90%, wherein the lens of the lower lens unit comprises a visible portion equal to or larger than the pattern of the photomask; and
an upper lens unit connected to the supporting frame of the cover and formed with a lens of a transmittance equal to or larger than 90%, wherein the lens of the upper lens unit comprises a visible portion equal to or larger than the pattern of the photomask;
wherein light is allowed to reach or leave the photomask via the visible portion of the lens of each of the lower and upper lens units when the photomask is contained in the pod.

2. The pod according to claim 1, wherein the lens of each of the lower and upper lens units is made of 99.995% pure quartz doped with less than 5 ppm of metal.

3. The pod according to claim 1, wherein the supporting frame of the base comprises a window corresponding to the photomask and a countersink bore in communication with the window, wherein the lower lens unit comprises a sealing ring inserted in the countersink bore with the lens thereof and a pressing frame connected to the supporting frame of the base to keep the sealing ring and the lens in the countersink bore.

4. The pod according to claim 1, wherein the supporting frame of the cover comprises a window corresponding to the photomask and a countersink bore in communication with the window, wherein the upper lens unit comprises a sealing ring inserted in the countersink bore with the lens thereof and a pressing frame connected to the supporting frame of the cover to keep the sealing ring and the lens in the countersink bore.

5. The pod according to claim 1, comprising two lateral lens units connected to two portions of the continuous wall of the cover corresponding to two opposite lateral faces of the photomask, wherein each of the lateral lens units comprises a lens of a transmittance equal to or larger than 90%, wherein the lens of each of the lateral lens units is made of quartz, and comprises a visible portion equal to or larger than each of the opposite lateral faces of the photomask, wherein light is allowed to reach or leave the photomask via the visible portion of the lens of each of the lower, upper and lateral lens units when the photomask is contained in the pod.

6. The pod according to claim 5, wherein the continuous wall of the cover comprises two windows corresponding to the photomask and two countersink bores in communication with the windows, wherein each of the lateral lens units comprises a sealing ring inserted in the countersink bore with the lens thereof and a pressing frame connected to the continuous wall of the cover to keep the sealing ring and the lens in the countersink bore.

7. A containing apparatus comprising the pod according to claim 1 and an internal pod inserted in the pod according to claim 1, wherein the internal pod comprises:
a base comprising a supporting frame;
a cover comprising a supporting frame corresponding to the supporting frame of the base of the internal pod and a continuous wall extending around the supporting frame of the cover of the internal pod and extending toward the base of the internal pod, wherein a chamber is defined between the cover and base of the internal pod to contain the photomask when the cover of the internal pod is connected to the base of the internal pod;
a lower lens unit connected to the supporting frame of the base of the internal pod and formed with a lens of a transmittance equal to or larger than 90%, wherein the lens of the lower lens unit of the internal pod comprises a visible portion equal to or larger than the pattern of the photomask; and
an upper lens unit connected to the supporting frame of the cover of the internal pod and formed with a lens of a transmittance equal to or larger than 90%, wherein the lens of the upper lens unit of the internal pod comprises a visible portion equal to or larger than the pattern of the photomask;
wherein light is allowed to reach or leave the photomask via the visible portion of the lens of each of the lower and upper lens units of the internal pod when the photomask is contained in the internal pod.

8. The containing apparatus according to claim 7, wherein the internal pod comprises two lateral lens units connected to two portions of the continuous wall of the cover of the internal pod corresponding to the opposite lateral faces of the photomask, wherein each of the lateral lens units of the internal pod comprises a lens of a transmittance equal to or larger than 90%, wherein the lens of each of the lateral lens units of the internal pod is made of quartz, and comprises a visible portion equal to or larger than each of the opposite lateral faces of the photomask, wherein light is allowed to reach or leave the photomask via the visible portion of the lens of each of the lower, upper and lateral lens units of the internal pod when the photomask is contained in the internal pod.

9. A pod for containing a photomask formed with two parallel faces, the pod comprising two primary lens units respectively connected to two portions of the pod corresponding to the faces of the photomask, wherein each of the primary lens units comprises a lens of a transmittance equal to or larger than 90%, wherein the lens of each of the primary lens units comprises a visible portion equal to or larger than a pattern formed on the photomask, wherein light is allowed to reach or leave the photomask via the visible portion of the lens of each of the primary lens units when the photomask is contained in the pod.

10. The pod according to claim 9, wherein the pod comprises two lateral lens units corresponding to two opposite lateral faces of the photomask, wherein each of the lateral lens unit comprises a lens of a transmittance equal to or larger than 90%, wherein the lens of each of the lateral lens units comprises a visible portion larger than the lateral faces of the photomask.
